(19) United States
(12) Patent Application Publication
(10) Pub. No.: US 2017/0287956 A1
(43) Pub. Date: Oct. 5, 2017

(54) SOLID-STATE IMAGING DEVICE

(71) Applicant: CANON KABUSHIKI KAISHA, Tokyo (JP)

(72) Inventor: Tomoyuki Tezuka, Sagamihara-shi (JP)

(21) Appl. No.: 15/460,022

(22) Filed: Mar. 15, 2017

(30) Foreign Application Priority Data
Mar. 31, 2016 (JP) 2016-070527

(51) Int. Cl. H01L 27/146; H04N 5/361; H04N 5/378; H04N 5/357

(52) U.S. Cl. CPC H01L 27/14612; H01L 27/14636; H01L 27/14621; H01L 27/14627; H04N 5/3572; H04N 5/361; H04N 5/378

(57) ABSTRACT

A solid-state imaging device includes a well formed of a first semiconductor region of a first conductivity type provided in a semiconductor substrate, a pixel provided in the well, and including a photoelectric conversion element, and a transistor including a second semiconductor region of a second conductivity type, a first contact electrode electrically connected to the first semiconductor region, and a second contact electrode electrically connected to the second semiconductor region. The first contact electrode has a contact area to the semiconductor substrate larger than that of the second contact electrode, and has different widths in a first direction and a second direction perpendicular to the first direction in a planar view. The width of the first contact electrode in the first direction is smaller than a width of the second contact electrode.

### BACKGROUND OF THE INVENTION

### Field of the Invention

The present invention relates to a solid-state imaging device.

### Description of the Related Art

A phenomenon in which the brightness of an image becomes nonuniform due to variations in well potential between a central portion and peripheral portion of a pixel region in a solid-state imaging device, i.e., so-called shading is known. Japanese Patent Application Laid-Open No. 2006-269546 describes a technique of suppressing shading by suppressing an increase in resistance component of a well interconnection by forming a plurality of well contact portions for applying a reference voltage to a well for each pixel.

As decrease of pixel size advances, however, the diameter of a contact hole decreases, and the contact resistance to the well contact portion increases.

Consequently, a voltage drop at the well contact portion sometimes makes it impossible to apply a desired bias voltage to the well, thereby distorting the waveform of an amplifier circuit, and causing shading. The contact resistance at the well contact portion can be decreased by performing high-concentration impurity ion implantation. However, high concentration impurity ion implantation sometimes causes a dark current by inducing a crystal defect in a semiconductor substrate, thereby causing a white spot defect.

### SUMMARY OF THE INVENTION

An object of the present invention is to provide a solid-state imaging device capable of suppressing shading and a white spot without decreasing the integration degree of pixels.

According to one aspect of the present invention, there is provided a solid-state imaging device including a well formed of a first semiconductor region of a first conductivity type provided in a semiconductor substrate, a pixel provided in the well, and including a photoelectric conversion element, and a transistor including a second semiconductor region of a second conductivity type, a first contact electrode electrically connected to the first semiconductor region, and a second contact electrode electrically connected to the second semiconductor region, wherein the first contact electrode has a contact area to the semiconductor substrate larger than that of the second contact electrode, and has different widths in a first direction and a second direction perpendicular to the first direction in a planar view, and wherein the width of the first contact electrode in the first direction is smaller than a width of the second contact electrode.

Further features of the present invention will become apparent from the following description of exemplary embodiments with reference to the attached drawings.

### BRIEF DESCRIPTION OF THE DRAWINGS

FIG. 1 is a block diagram illustrating an outline of the arrangement of a solid-state imaging device according to the first embodiment of the present invention.

FIG. 2 is a view illustrating an example of a pixel circuit of the solid-state imaging device according to the first embodiment of the present invention.

FIG. 3 is a plan view of the solid-state imaging device according to the first embodiment of the present invention.

FIG. 4 is a schematic cross-sectional view of the solid-state imaging device according to the first embodiment of the present invention.

FIG. 5 is a plan view of a solid-state imaging device according to a comparative example.

FIGS. 6A and 6B are enlarged plan views of well contact portions.

FIGS. 7A and 7B are schematic cross-sectional views of a well contact portion of the solid-state imaging device according to the comparative example.

FIGS. 8A and 8B are schematic cross-sectional views of a well contact portion of the solid-state imaging device according to the first embodiment of the present invention.

FIG. 9 is a schematic view illustrating an imaging system according to the second embodiment of the present invention.

### DESCRIPTION OF THE EMBODIMENTS

Preferred embodiments of the present invention will now be described in detail in accordance with the accompanying drawings.

### First Embodiment

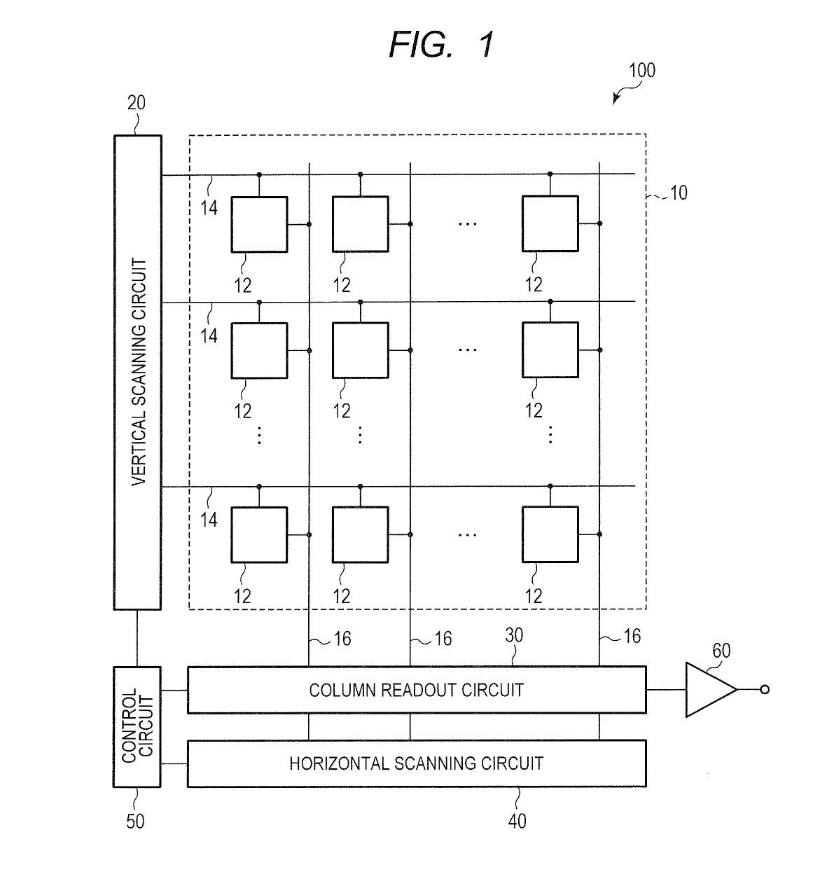

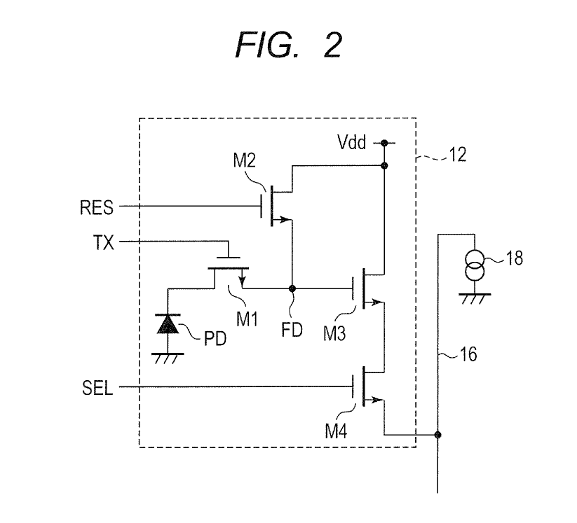

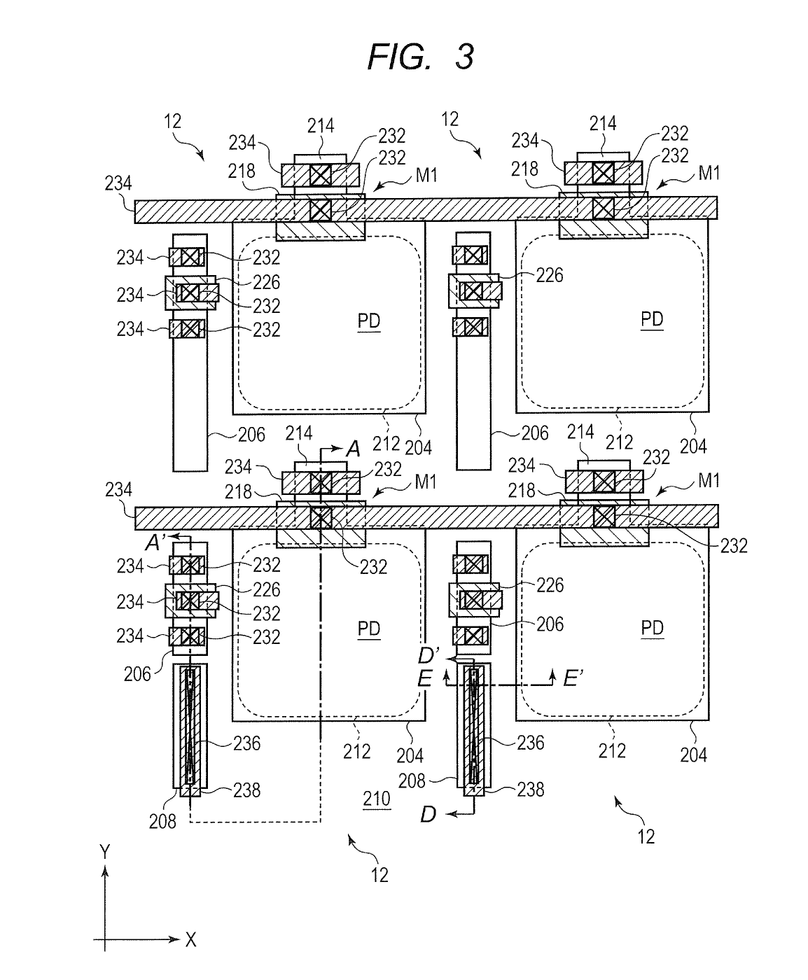

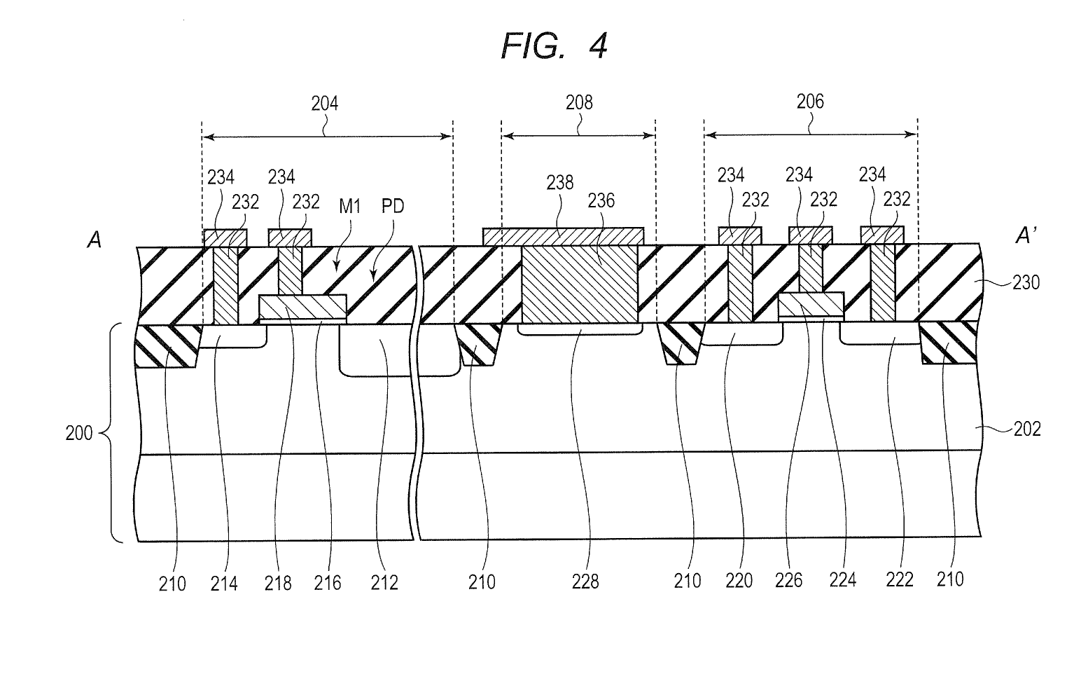

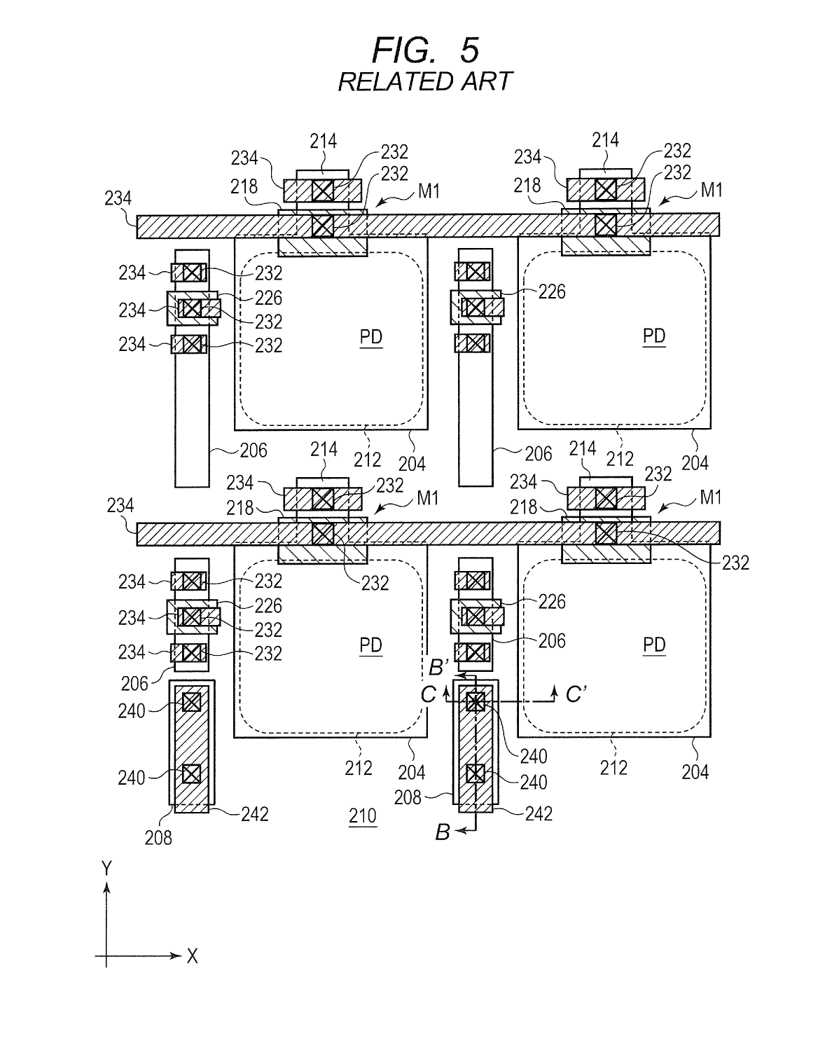

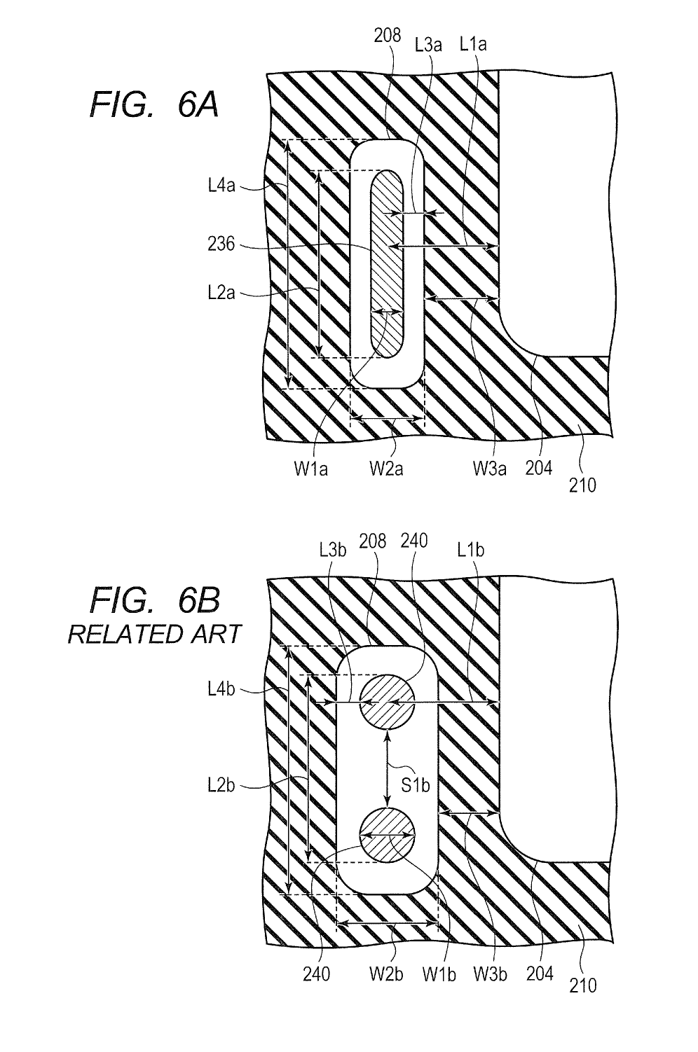

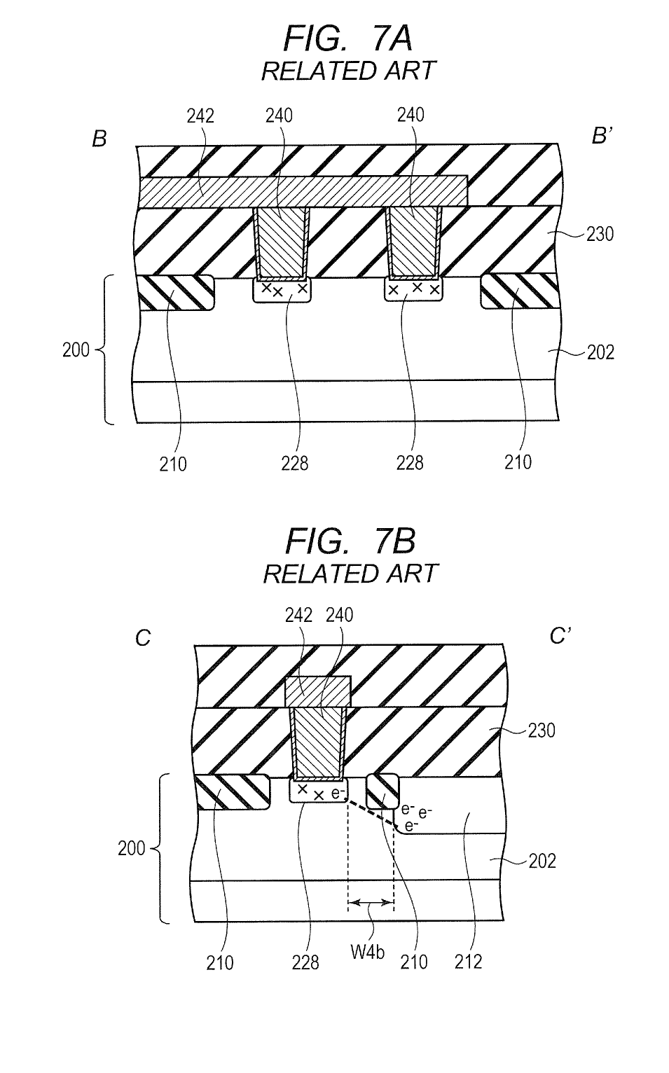

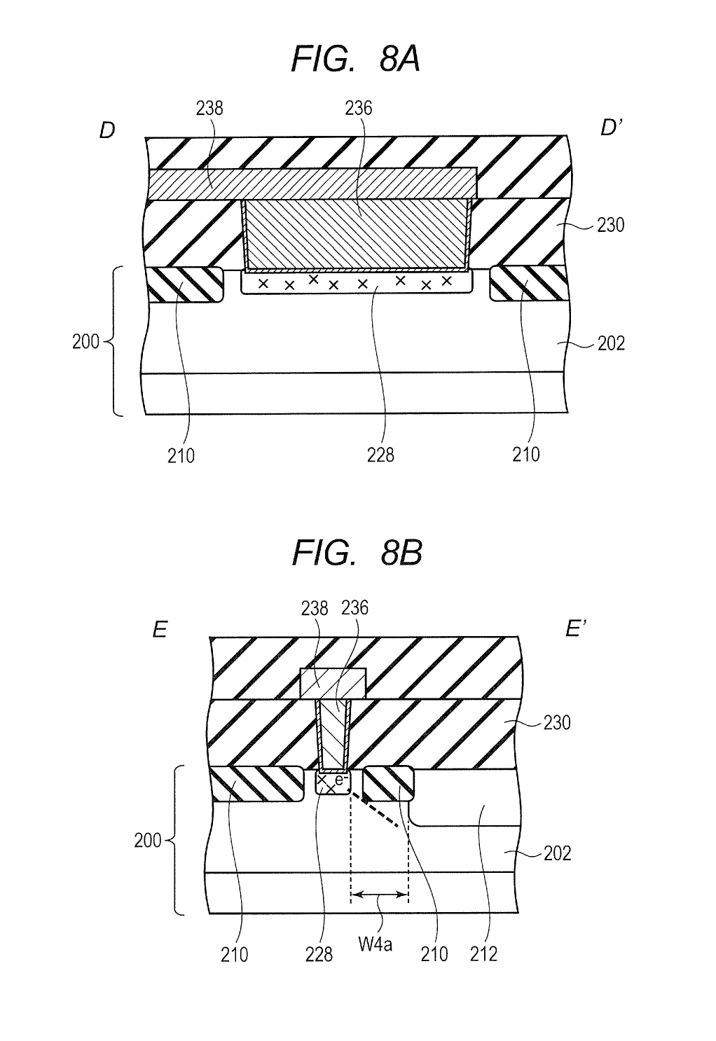

A solid-state imaging device according to a first embodiment of the present invention will be explained below with reference to FIGS. 1 to 8B. FIG. 1 is a block diagram illustrating an outline of the arrangement of the solid-state imaging device according to the present embodiment. FIG. 2 is a view illustrating an example of a pixel circuit of the solid-state imaging device according to the present embodiment. FIG. 3 is a plan view of the solid-state imaging device according to the present embodiment. FIG. 4 is a schematic cross-sectional view of the solid-state imaging device according to the present embodiment. FIG. 5 is a plan view of a solid-state imaging device according to a comparative example. FIGS. 6A and 6B are enlarged plan views of well contact portions. FIGS. 7A and 7B are schematic cross-sectional views of a well contact portion of the solid-state imaging device according to the comparative example. FIGS. 8A and 8B are schematic cross-sectional views of a well contact portion of the solid-state imaging device according to this embodiment.

As illustrated in FIG. 1, a solid-state imaging device 100 according to the present embodiment includes a pixel region 10, a vertical scanning circuit 20, a column readout circuit 30, a horizontal scanning circuit 40, a control circuit 50, and an output circuit 60.

In the pixel region 10, a plurality of pixels 12 are arranged in a matrix over a plurality of rows and a plurality of columns. A control signal line 14 is arranged in each row of the pixel array in the pixel region 10 to extend in the row direction (the horizontal direction in FIG. 1), respectively. The control signal line 14 is connected to pixels 12 arranged in the row direction, thereby forming a common signal line for the pixels 12. Also, a vertical output line is arranged in each column of the pixel array in the pixel region 10 to extend in the column direction (the vertical direction in FIG. 1). The vertical output line 16 is connected to pixels 12 arranged in the column direction, thereby forming a common signal line for the pixels 12.

The control signal lines 14 on the individual rows are connected to the vertical scanning circuit 20. The vertical scanning circuit 20 is a circuit unit which supplies, to the pixel 12 via the control signal line 14, a control signal for driving a readout circuit in the pixel 12 when reading out a pixel signal from the pixel 12. One end of the vertical output line 16 in each column is connected to the column readout circuit 30. A pixel signal read out from the pixel 12 is input to the column readout circuit 30 via the vertical output line 16. The column readout circuit 30 is a circuit unit which performs predetermined signal processing, such as an amplification process or AD conversion process, on the pixel signal readout from the pixel 12. The column readout circuit 30 may include, e.g., a differential amplifier circuit, sample-and-hold circuit, and AD conversion circuit.

The horizontal scanning circuit 40 is a circuit unit which supplies, to the column readout circuit 30 for each column, a control signal for sequentially transferring pixel signals processed in the column readout circuit 30 to the output circuit 60. The control circuit 50 is a circuit unit which supplies control signals for controlling the operations and operation timings of the vertical scanning circuit 20, column readout circuit 30, and horizontal scanning circuit 40. The output circuit 60 is a circuit unit which includes a buffer amplifier, differential amplifier, and the like, and outputs the pixel signal read out from the column readout circuit 30 to an external signal processing unit of the solid-state imaging device.

As illustrated in FIG. 2, each pixel 12 includes a photoelectric conversion element PD, a transfer transistor M1, a reset transistor M2, an amplifier transistor M3, and a select transistor M4. The photoelectric conversion element PD is a photodiode or the like, and has an anode connected to a ground voltage line, and a cathode connected to the drain of the transfer transistor M1. The source of the transfer transistor M1 is connected to the source of the reset transistor M2 and the gate of the amplifier transistor M3. A connection node of the source of the transfer transistor M1, the source of the reset transistor M2, and the gate of the amplifier transistor M3 is a so-called floating diffusion (FD), and forms a charge-voltage conversion unit including the parasitic capacitance of the node. The drains of the reset transistor M2 and amplifier transistor M3 are connected to a power supply voltage line (Vdd). The source of the amplifier transistor M3 is connected to the drain of the select transistor M4. The source of the select transistor M4 is connected to the vertical output line 16. The other end portion of the vertical output line 16 is connected to a current source 18 for forming a source follower circuit by supplying a bias electric current to the amplifier transistor M3.

In this circuit configuration illustrated in FIG. 2, each of the control signal lines 14 includes a transfer gate signal line TX, a reset signal line RES, and a select signal line SEL. The transfer gate signal line TX is connected to the gate of the transfer transistor M1. The reset signal line RES is connected to the gate of the reset transistor M2. The select signal line SEL is connected to the gate of the select transistor M4.

FIG. 3 illustrates an example of the planar layout of four pixels 12 extracted from the pixel region 10 illustrated in FIG. 1. FIG. 4 is a schematic cross-sectional view taken along a line A-A′ in FIG. 3.

A p-type semiconductor region 202 forming a p-well is provided in the surface portion of an n-type semiconductor substrate 200. A device isolation region 210 defining active regions 204, 206, and 208 is provided in the surface portion of the p-type semiconductor region 202. The device isolation region 210 is formed by STI (Shallow Trench Isolation) method or the like.

In the active region 204, the photoelectric conversion element PD and the transfer transistor M1 out of the constituent elements of the pixel 12 are arranged. N-type semiconductor regions 212 and 214 are arranged apart from each other in the surface portion of the p-type semiconductor region 202 in the active region 204. The n-type semiconductor region 212 forms a p-n junction together with the p-type semiconductor region 202, thereby forming a photodiode as the photoelectric conversion element PD. The photoelectric conversion element PD may also be a buried photodiode in which a p-type semiconductor region is further provided in the surface portion of the n-type semiconductor region 212. A gate electrode 218 is provided over the p-type semiconductor region 202 between the n-type semiconductor regions 212 and 214 with a gate insulating film 216 interposed therebetween. Thus, the transfer transistor M1 including the n-type semiconductor region 212 as a drain region, the n-type semiconductor region 214 as a source region, and the gate electrode 218 as a gate electrode is formed. The n-type semiconductor region 214 is also an FD region. Interconnections 234 are electrically connected to the n-type semiconductor region 214 and gate electrode 218 via contact plugs 232 provided in an interlayer insulating film 230. The contact plugs 232 may be formed of, e.g., titanium (Ti) or titanium nitride (TiN) as a barrier metal, and tungsten (W) as a filling metal.

In the active region 206, the reset transistor M2, amplifier transistor M3, and select transistor M4 of the constituent elements out of the pixel 12 are arranged. To simplify the drawings, only one of the reset transistor M2, amplifier transistor M3, and select transistor M4 is shown in the active area 206 illustrated in FIGS. 3 and 4. N-type semiconductor regions 220 and 222 are arranged apart from each other in the surface portion of the p-type semiconductor region 202 in the active region 206. A gate electrode 226 is provided over the p-type semiconductor region 202 between the n-type semiconductor regions 220 and 222 with a gate insulating film 224 interposed therebetween. Thus, the transistor (the reset transistor M2, amplifier transistor M3, or select transistor M4) including the n-type semiconductor regions 220 and 222 as a source region and drain region, and the gate electrode 226 as a gate electrode is formed. Interconnections 234 are connected to the n-type semiconductor regions 220 and 222 and gate electrode 226 via contact plugs 232 provided in the interlayer insulating film 230.

The active region 208 is a portion where a contact (well contact) to the p-type semiconductor region 202 forming the well is formed. This well contact is an electrical connecting portion to the semiconductor substrate 200 for supplying a voltage to the well (p-type semiconductor region 202). One reason of forming the well contact is to fix the bias voltage of the signal amplifier circuit by making it possible to apply a constant voltage to the well. FIG. 3 illustrates an example in which the active region 208 is provided in only two lower pixels 12 of the four pixels 12. In the surface portion of the p-type semiconductor region 202 in the active region 208, a p-type semiconductor region 228 having an impurity concentration higher than that of the p-type semiconductor region 202 is formed. An interconnection 238 is connected to the p-type semiconductor region 228 via a contact plug 236 provided in the interlayer insulating film 230. The contact plug 236 may be formed of, e.g., titanium (Ti) or titanium nitride (TiN) as a barrier metal, and tungsten (W) as a filling metal.

Over the interconnections 234 and 238, other interconnections necessary to form the pixel circuit illustrated in FIG. 2, color filters, microlenses, and the like are formed, although none of them are illustrated and a detailed explanation thereof will be omitted.

As described above, the photoelectric conversion element PD, transfer transistor M1, reset transistor M2, amplifier transistor M3, and select transistor M4 forming one pixel 12 are provided in the common well (p-type semiconductor region 202). Although FIG. 4 does not illustrate the relationship with adjacent pixels 12, a plurality of pixels 12 forming the pixel region 10 may be arranged in one common well, and may also be arranged in different wells for each predetermined block. For example, the active regions 208 are regularly arranged in some pixels 12 in the pixel region 10, so as to be able to hold the well potential uniform in a plane via the contact of the active regions 208. In one embodiment, one well contact is formed in each region of 10 μm² to 3,500 μm². Note that the active regions 208 may also be arranged in all pixels 12 in the pixel region 10.

In the solid-state imaging device according to the present embodiment, the shape of the contact electrode of the well contact portion is different from the shape of the contact electrode to be connected to the source and drain of the transistor forming the pixel circuit in a planar view. That is, the shape of the contact electrode (contact plug 232) to be electrically connected to the source or drain of the transistor has almost equal widths along a first direction (the X direction in FIG. 3) and a second direction (the Y direction in FIG. 3) perpendicular to the first direction. By contrast, the shape of the contact electrode (contact plug 236) to be electrically connected to the well has different widths along the first and second directions. More specifically, the width along the first direction of the contact electrode to be electrically connected to the well is smaller than the width of the contact electrode to be connected to the source and drain of the transistor. Also, the width along the second direction of the contact electrode to be electrically connected to the well is larger than the width of the contact electrode to be connected to the source and drain of the transistor. That is, the contact electrode to be electrically connected to the well has an elongated shape having different widths in the vertical direction and horizontal direction in a planar view. The longitudinal direction in a planar view of the contact electrode to be electrically connected to the well may be the Y direction as illustrated in FIG. 3, the X direction, or another direction.

As indicated by, e.g., a contact plug 240 to which an interconnection 242 is connected in FIG. 5, the contact electrode to be electrically connected to the well may also have the same shape as that of the contact electrode (contact plug 232) to be connected to the source and drain of the transistor. Furthermore, the contact resistance at the well contact portion can be reduced by forming a plurality of (two in FIG. 5) contact plugs 240.

From the viewpoint of suppression of shading and a white spot, however, the shape of the well contact electrode of the present embodiment illustrated in FIG. 3 is more favorable than that of a well contact electrode of a comparative example illustrated in FIG. 5. Advantageous effects of the well contact portion of the present embodiment will be explained below with reference to FIGS. 6A and 6B by way of practical examples in comparison with the well contact portion of the comparative example.

FIG. 6A is an enlarged plan view of the well contact portion of the present embodiment illustrated in FIG. 3. FIG. 6B is an enlarged plan view of the well contact portion of the comparative example illustrated in FIG. 5. FIGS. 6A and 6B each depict a finished shape in which each pattern has rounded corners, by taking account of the influence of the optical proximity effect when forming the pattern by photolithography by using a rectangular mask pattern as illustrated in each of FIGS. 3 and 5. To simplify the drawings, interconnections in upper layers of the contact plugs 236 and 240 are not illustrated.

Assume that the contact plugs 236 and 240 are so arranged that a distance L1a from the active region 204 to the center of the contact plug 236 is equal to a distance L1b from the active region 204 to the center of the contact plug 240.

Assuming that a width W1b of the contact plug 240 is about 0.14 μm in the well contact portion of the comparative example illustrated in FIG. 6B, a space S1b between the contact plugs 240 is about 0.26 μm. When two contact plugs 240 are arranged with the space S1b, a length L2b of the region where the two contact plugs 240 are arranged is about 0.54 μm. Assuming that an overlap amount L3b which is determined by the alignment margin of the contact plug 240 with respect to the active region 208 is 0.05 μm, a width W2b of the active region 208 is about 0.24 μm, and a length L4b of the active area 208 is about 0.64 μm.

On the other hand, assume that the contact plug 236 having a width W1a and a length L2a equal to the length L2b is formed in the well contact portion of the present embodiment illustrated in FIG. 6A. By using the contact plug 236 like this, the contact area of the contact plug 236 with respect to the semiconductor substrate 200 can be made larger than the contact area obtained by the two contact plugs 240 illustrated in FIG. 6B.

Also, even when the width W1a is made smaller than the width W1b of the contact plug 240 illustrated in FIG. 6B, the contact area of the contact plug 236 with respect to the semiconductor substrate 200 may be made larger than the contact area obtained by the two contact plugs 240. For example, when the width W1a of the contact plug 236 is about 0.1 μm, the contact area of the contact plug 236 is about 1.7 times the total contact area of the two contact plugs 240. In this case, assuming that an overlap amount L3a which is determined by the alignment margin of the contact plug 240 with respect to the active region 208 is 0.05 μm, a width W2a of the active region 208 is about 0.20 μm, and a length L4a of the active region 208 is about 0.64 μm.

As described above, when the contact electrode of the present embodiment is used in the well contact portion, the contact area of the contact plug 236 with respect to the semiconductor substrate 200 can be increased without increasing the area of the active region 208 necessary in the well contact portion. This makes it possible to reduce the contact resistance between the contact plug 236 and the semiconductor substrate 200 (the p-well), thereby suppressing shading.

In addition, since the area of the active region 208 may be decreased, a separation width W3a between the active region 204 and the active region 208 may be made larger than a separation width W3b in the comparative example. Increasing the separation width W3a has a white spot suppressing effect. This white spot suppressing effect will be explained below with reference to FIGS. 7A to 8B.

FIG. 7A is a schematic cross-sectional view taken along a line B-B′ in FIG. 5. FIG. 7B is a schematic cross-sectional view taken along a line C-C′ in FIG. 5. FIG. 8A is a schematic cross-sectional view taken along a line D-D′ in FIG. 3. FIG. 8B is a schematic cross-sectional view taken along a line E-E′ in FIG. 3.

Impurity ion implantation is normally performed in the connecting portion between the contact plug 240 and the well via a contact hole in which the contact plug 240 is buried, in order to reduce the contact resistance between the contact plug 240 and the semiconductor substrate 200. An impurity region formed by this impurity ion implantation is the p-type semiconductor region 228. The p-type semiconductor region 228 is formed in the semiconductor substrate 200 in self-alignment with the contact hole. The p-type semiconductor region 228 may also be formed by ion implantation using a mask before the contact hole is formed.

The contact resistance between the contact plug 240 and the semiconductor substrate 200 may also be reduced by increasing the impurity concentration of the p-type semiconductor region 228. To increase the impurity concentration of the p-type semiconductor region 228, however, the dosage of the impurity must be increased, and this increases damage to the semiconductor substrate 200. This damage inflicted on the semiconductor substrate 200 by ion implantation can be removed to some extent by thermal processing after that, but no sufficient thermal load may be applied any longer as the decrease of device size advances. As a consequence, crystal defects such as point defects indicated by marks x and a linear defect indicated by a dotted line in FIGS. 7A and 7B sometimes remain in or around the p-type semiconductor region 228. If crystal defects like these reach the photoelectric conversion unit, i.e., the n-type semiconductor region 212, as illustrated in FIG. 7B, a flow of electrons (e⁻) flowing through the defects, i.e., a dark current increases, and this causes a white spot.

The influence of the crystal defects can be suppressed by widening the spacing between the p-type semiconductor region 228 and the n-type semiconductor region 212, but this may become a large factor which hinders downsizing of the pixels 12. Also, forming a plurality of contact plugs 240 in one pixel 12 is an effective means for increasing the contact area between the contact plug 240 and the semiconductor substrate 200, but this increases a dark current generating source.

When compared to the structure of the comparative example, the solid-state imaging device according to the present embodiment can reduce the contact resistance in the well contact portion, so the impurity concentration of the p-type semiconductor region 228 may be decreased accordingly. For example, the impurity concentration of the p-type semiconductor region 228 may be made lower than that of the source and drain of the p-type transistor formed in the peripheral circuit region (e.g., the vertical scanning circuit 20, column readout circuit 30, horizontal scanning circuit 40, control circuit 50, and output circuit 60). This makes it possible to reduce the generation probability of the crystal defects which cause the dark current. In addition, since the width W2a of the active region 208 may be decreased, the separation width W3a between the active region 204 and the active region 208 may be made larger than the separation width W3b between the active region 204 and the active region 208 without hindering downsizing of the pixels 12. That is, as illustrated in FIG. 8B, a separation width W4a between the p-type semiconductor region 228 and the n-type semiconductor region 212 may be made larger than a separation width W4b between the p-type semiconductor region 228 and the n-type semiconductor region 212. Accordingly, it is possible to decrease the probability at which a crystal defect having occurred in or around the p-type semiconductor region 228 reaches the n-type semiconductor region 212, thereby suppressing a white spot.

As described above, according to the present embodiment, shading and a white spot can be suppressed without decreasing the pixel integration degree.

### Second Embodiment

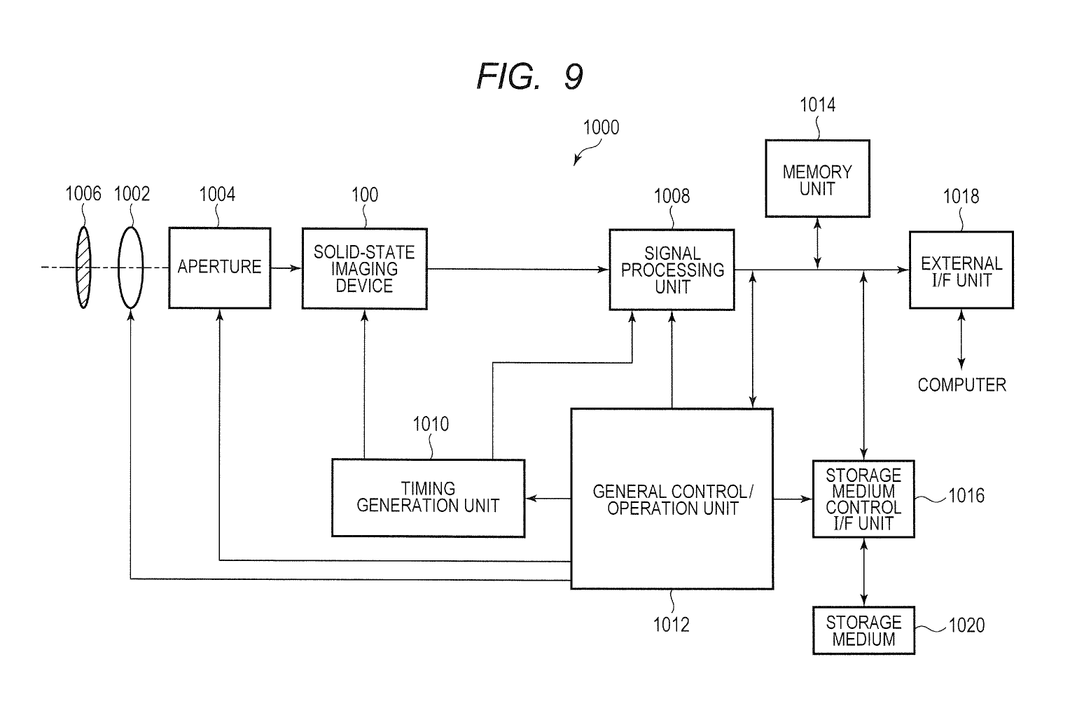

An imaging system according to a second embodiment of the present invention will be explained with reference to FIG. 9. FIG. 9 is a block diagram illustrating an outline of the arrangement of the imaging system according to the present embodiment. The same reference numerals as in the solid-state imaging device according to the first embodiment illustrated in FIGS. 1 to 8B denote the same constituent elements, and an explanation thereof will be omitted or simplified.

The solid-state imaging device 100 described in the first embodiment is applicable to various imaging systems. Examples of imaging systems to which the device is applicable are a digital still camera, digital camcorder, surveillance camera, copying machine, facsimile apparatus, cell phone, in-vehicle camera, and observation satellite. The imaging systems also include a camera module including an optical system such as a lens and the solid-state imaging device. FIG. 9 is a block diagram of a digital still camera as an example of these imaging systems.

An imaging system 1000 illustrated in FIG. 9 includes a solid-state imaging device 100, a lens 1002 for forming an optical image of an object on the solid-state imaging device 100, an aperture 1004 for varying the amount of light passing through the lens 1002, and a barrier 1006 for protecting the lens 1002. The lens 1002 and aperture 1004 form an optical system for conversing light to the solid-state imaging device 100. The solid-state imaging device 100 is the solid-state imaging device 100 explained in the first embodiment, and converts the optical image formed by the lens 1002 into image data.

The imaging system 1000 also includes a signal processing unit 1008 for processing an output signal from the solid-state imaging device 100. The signal processing unit 1008 performs AD conversion which converts an analog signal output from the solid-state imaging device 100 into a digital signal. In addition, the signal processing unit 1008 performs an operation of performing various kinds of correction and compression as needed, and outputting the image data. An AD converter as a part of the signal processing unit 1008 can be formed on a semiconductor substrate on which the solid-state imaging device 100 is formed, and can also be formed on a semiconductor substrate different from the solid-state imaging device 100. Furthermore, the solid-state imaging device 100 and signal processing unit 1008 can be formed on the same semiconductor substrate.

The imaging system 1000 further includes a memory unit 1014 for temporarily storing image data, and an external interface unit (external I/F unit) 1018 for communicating with, e.g., an external computer. In addition, the imaging system 1000 includes a storage medium 1020 such as a semiconductor memory for storing or reading out imaged data, and a storage medium control interface unit (storage medium control I/F unit) 1016 for storing or reading out data in or from the storage medium 1020. Note that the storage medium 1020 can be incorporated into the imaging system 1000, and can also be detachable.

Furthermore, the imaging system 1000 includes a general control/operation unit 1012 for driving the whole digital still camera and performing various kinds of arithmetic processing, and a timing generation unit 1010 for outputting various timing signals to the solid-state imaging device 100 and signal processing unit 1008. Note that the timing signals may also be externally input, and the imaging system 1000 need only include at least the solid-state imaging device 100, and the signal processing unit 1008 for processing output signals from the solid-state imaging device 100.

By thus configuring the imaging system 1000 to which the solid-state imaging device 100 according to the first embodiment is applied, it is possible to implement a high-performance imaging system capable of forming a high-quality image by suppressing shading and a white spot.

[Modifications]

The present invention is not limited to the above embodiments, and various modifications can be made.

For example, the above embodiment is explained by taking the case in which the readout circuit of the pixel 12 is formed by an n-channel MOS transistor as an example. However, the readout circuit of the pixel 12 may also be formed by a p-channel MOS transistor. In this case, the conductivity type of each semiconductor region explained in the embodiment becomes the opposite conductivity type. Note that the names “source” and “drain” of each transistor described in the above embodiment are examples, and these names may also be switched in accordance with, e.g., the conductivity type of a transistor or a function of interest.

Note also that the pixel circuit illustrated in FIG. 2 is an example, and the present invention is not limited to this. For example, it is also possible to form a pixel configuration capable of a global electronic shutter operation by forming a second transfer transistor between the transfer transistor M1 and the FD region. Furthermore, the pixel 12 may also include a plurality of photoelectric conversion elements PD, and a plurality of corresponding transfer transistors M1. In addition, the planar pixel layout illustrated in FIG. 3 is an example, and the present invention is not limited to this.

Also, the imaging system disclosed in the second embodiment is an example of an imaging system to which the solid-state imaging device of the present invention is applicable, and an imaging system to which the solid-state imaging device of the present invention is applicable is not limited to the configuration shown in FIG. 9.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-070527, filed Mar. 31, 2016 which is hereby incorporated by reference herein in its entirety.

What is claimed is:

1. A solid-state imaging device comprising:
a well formed of a first semiconductor region of a first conductivity type provided in a semiconductor substrate;
a pixel provided in the well, and including a photoelectric conversion element, and a transistor including a second semiconductor region of a second conductivity type;
a first contact electrode electrically connected to the first semiconductor region; and
a second contact electrode electrically connected to the second semiconductor region,
wherein the first contact electrode has a contact area to the semiconductor substrate larger than that of the second contact electrode, and has different widths in a first direction and a second direction perpendicular to the first direction in a planar view, and
wherein the width of the first contact electrode in the first direction is smaller than a width of the second contact electrode.

2. The solid-state imaging device according to claim 1, further comprising a third semiconductor region of the first conductivity type provided between the first semiconductor region and the first contact electrode, and having an impurity concentration higher than that of the first semiconductor region.

3. The solid-state imaging device according to claim 2, wherein the third semiconductor region is formed in self-alignment with a contact hole where the first contact electrode is provided.

4. The solid-state imaging device according to claim 2, wherein the impurity concentration of the third semiconductor region is lower than that of a fourth semiconductor region forming one of a source and a drain of a transistor formed in a peripheral circuit region.

5. The solid-state imaging device according to claim 3, wherein the impurity concentration of the third semiconductor region is lower than that of a fourth semiconductor region forming one of a source and a drain of a transistor formed in a peripheral circuit region.

6. The solid-state imaging device according to claim 1, wherein a first active region where the first contact electrode is provided and a second active region where the photoelectric conversion element is provided are adjacent to each other.

7. The solid-state imaging device according to claim 2, wherein a first active region where the first contact electrode is provided and a second active region where the photoelectric conversion element is provided are adjacent to each other.

8. The solid-state imaging device according to claim 3, wherein a first active region where the first contact electrode is provided and a second active region where the photoelectric conversion element is provided are adjacent to each other.

9. The solid-state imaging device according to claim 4, wherein a first active region where the first contact electrode is provided and a second active region where the photoelectric conversion element is provided are adjacent to each other.

10. The solid-state imaging device according to claim 5, wherein a first active region where the first contact electrode is provided and a second active region where the photoelectric conversion element is provided are adjacent to each other.

11. An imaging system comprising:
a solid-state imaging device; and
a signal processing unit configured to process a signal from the solid-state imaging device, wherein
the solid-state imaging device including:
a well formed of a first semiconductor region of a first conductivity type provided in a semiconductor substrate;
a pixel provided in the well, and including a photoelectric conversion element, and a transistor including a second semiconductor region of a second conductivity type;
a first contact electrode electrically connected to the first semiconductor region; and
a second contact electrode electrically connected to the second semiconductor region,
wherein the first contact electrode has a contact area to the semiconductor substrate larger than that of the second contact electrode, and has different widths in a first direction and a second direction perpendicular to the first direction in a planar view, and
wherein the width of the first contact electrode in the first direction is smaller than a width of the second contact electrode.
